(19) United States
(12) Patent Application Publication
(10) Pub. No.: US 2021/0130173 A1
(43) Pub. Date: May 6, 2021

(54) SUPER-FLEXIBLE HIGH ELECTRICAL AND THERMAL CONDUCTIVITY FLEXIBLE BASE MATERIAL AND PREPARATION METHOD THEREOF

(71) Applicant: SHENZHEN DANBOND TECHNOLOGY CO., LTD, Shenzhen (CN)

(72) Inventor: Ping LIU, Shenzhen, Guangdong (CN)

(21) Appl. No.: 17/083,309

(22) Filed: Oct. 29, 2020

(30) Foreign Application Priority Data
Oct. 30, 2019 (CN) 201911059818.X

(51) Int. Cl. C01B 32/184; H05K 1/11; C08G 73/10; H05K 1/03; C08J 5/18

(52) U.S. Cl. CPC C01B 32/184; H05K 1/118; C08J 5/18; H05K 1/0393; C08G 73/10

(57) ABSTRACT

The present invention discloses a super-flexible high electrical and thermal conductivity flexible base material and a preparation method thereof, wherein the method comprises the steps of: S1. carbonizing and blackleading a polyimide thin film, doping nano-metal to the polyimide thin film, and performing ion implantation and ion exchange; S2. performing plasma irradiation modification treatment on a surface of the material obtained after the step S1 to form a heterogeneous surface layer; and S3. forming a metal conductor layer on the heterogeneous surface layer by physical vapor deposition (PVD) or chemical vapor deposition (CVD), so as to obtain the super-flexible high-ductility high electrical and thermal conductivity flexible base material. The method can obtain the C-C-FPC, C-C-COF or C-C-FCCL flexible circuit base material with super flexibility, high ductility, high electrical conductivity, high thermal conductivity and high frequency performance.

### CROSS REFERENCE TO RELATED APPLICATION

This application claims priority to CN patent application NO. 201911059818.X filed on 2019 Oct. 30. The contents of the above-mentioned application are all hereby incorporated by reference.

### BACKGROUND OF THE INVENTION

### 1. Field of the Invention

The present invention relates to the field of electronic circuit board materials, in particular to a super-flexible high electrical and thermal conductivity flexible base material and a preparation method thereof.

### 2. Description of the Prior Art

With the advent of the 5G era and the application of mobile phone flexible screens, flexible electronic technology is a popular integration technology in the future. FCCL, a flexible electronic base material for flexible printed circuit applications, is facing new challenges. The development of 5G application has revolutionized the traditional communication devices and promoted the emergence of new flexible electronic materials to meet the requirements of high temperature, high pressure, high frequency, high speed, high density and low power consumption. Traditional flexible electronic materials are facing changes.

Flexible electronic materials comprise a flexible printed circuit (FPC), a COF, a basis material FCCL, broadly speaking, including the fields of electronic component connections, device integration substrates, and semiconductor package substrates. Due to the outstanding heat resistance, chemical resistance, bending fatigue resistance, excellent electronic physical property and stable size, the rapid development of the electronic industry is promoted. The flexible electronic materials can be used in everywhere including connecting the smart phone core with a circuit, packaging a chip on a flexible substrate, connecting a device with a switch. Being responsible for all the work in the field of flexible circuits such as electronic products and notebook computers, the flexible FCCL is a key material which plays a role in conducting connection, mechanical strength bending and device insulation.

Flexible electronic material FCCL is a flexible printed circuit board (FPC/COF) circuit processing substrate with or without adhesive. FCCL is called two-layer flexible copper clad laminate (2L-FCCL), which is mainly used for high-end FPC and COF (Chip On Flex/Chip On Film) packaging substrate. A three-layer method is used for coating a polyimide thin film, an adhesive is used for compounding with a copper foil to form a substrate called a clad copper plate, and in another sputtering method, a copper plating layer is electroplated on a polyimide thin film, but the method has the defects of complex process, high cost, easiness in short circuit, serious environmental protection problem and the like.

### SUMMARY OF THE INVENTION

The present invention mainly aims to overcome the above defects in the prior art, and provides a super-flexible high electrical and thermal conductivity flexible base material and a preparation method thereof.

In order to achieve the above object, the present invention adopts the following technical solution:

A preparation method of a super-flexible high electrical and thermal conductivity flexible base material, comprises the steps of:

S1. carbonizing and blackleading the polyimide thin film, doping nano-metal to the polyimide thin film, and performing ion implantation and ion exchange;

S2. performing plasma irradiation modification treatment on the surface of the material obtained after the step S1 to form a heterogeneous surface layer; and

S3. forming a metal conductor layer on the heterogeneous surface layer by physical vapor deposition (PVD) or chemical vapor deposition (CVD), so as to obtain the super-flexible high-ductility high electrical and thermal conductivity flexible base material.

Further:

in step S1, transition nano-metal is doped, preferably selected from group VIII cobalt, nickel, ruthenium and lanthanum, preferably, the nanometer is a mixture of 2,000 nm and 400 nm; preferably, the nano-metal forming the upper layer of the surface of the material is cobalt and the nano-metal of the lower layer of the surface is nickel, more preferably, the thickness of the lower layer of the surface is 500 nm.

In step S1, two or more of the three protective gases N, Ar, Ne are mixed and used in the carbonization and blackleading treatment, preferably 50% of N and 50% of Ar are mixed and used in the carbonization, preferably 50% of Ar and 50% of Ne are mixed and used in the blackleading process; preferably, the nano-metal is doped with the protective gas at a pressure of 50 Kpa.

Before step S1, further comprising the steps of manufacturing the polyimide thin film:

S01. hybridizing anhydride containing phenyl with diamine to obtain a thermoplastic polyimide resin precursor; and

S02. preparing a polyimide thin film by using the thermoplastic polyimide resin precursor;

in step S01, dissolving 30-60 parts by volume of 2,2-bis[4-(4-aminophenoxy) phenyl] propane (BAPP), 30-60 parts by volume of 4,4′-diaminodiphenyl ether (4,4′-ODA) and 7-14 parts by volume of diamino dianthryl ether in N,N-dimethylformamide (DMF), adding 30-60 parts by volume of 3,3′,4,4′-benzophenone tetracarboxylic dianhydride (BTDA), then adding 20-40 parts by volume of pyromellitic dianhydride (PMDA), after a period of reaction, additionally adding 3,3′,4,4′-benzophenone tetracarboxylic dianhydride (BTDA) and/or pyromellitic dianhydride (PMDA) and obtaining a polyimide resin precursor with thermoplasticity, heat resistance and freedom degree; preferably, the total moles of 3,3′,4,4′-benzophenone tetracarboxylic dianhydride (BTDA) and pyromellitic dianhydride (PMDA) is made approximately equal to the total moles of 2,2-bis [4-(4-aminophenoxy) phenyl] propane (BAPP), 4,4′-diaminodiphenyl ether (4,4′-ODA) and diamino dianthryl ether.

In step S02, a diamino dianthryl ether is used for gel synthesis with the thermoplastic polyimide resin precursor, and a blowout type spraying method is used for uniformly forming a film to obtain a heterogeneous hybridized polyimide thin film; preferably, the gel synthesis is performed above −100° C., preferably the diamino dianthryl ether has a hybridized molecular weight greater than 1,000,000; preferably, the hybridization time is 5 h or more, preferably 6.5 h.

In step S3, physical vapor deposition (PVD) is performed by a magnetron sputtering technique; preferably, the purity of the conductor target source is 99.999%, and is selected from Al, Ni, Cu, Si, Au, Ag, microcrystalline silver powder, preferably selected from nickel, copper, silver copper powder and microcrystalline silver powder; preferably, the sputter thickness is 2,000 nm, 1,000 nm or 500 nm, more preferably 500 nm.

In step S3, physical vapor deposition (PVD) or chemical vapor deposition (CVD) is performed by evaporation.

The preparation method further comprises the steps of:

S4. annealing the material obtained in the step S3, preferably by a laser annealing technology.

In step S4, annealing treatment is performed at a temperature not lower than 3,200° C. to make the base film material expand, deoxidize and replace, transform crystal phase change to meet the high-orientation requirement of the superlattice.

The super-flexible high electrical and thermal conductivity flexible base material is a super-high-conductivity and thermal-conductivity flexible base material obtained by the preparation method.

The present invention has the following beneficial effects:

The present invention provides a super-flexible high electrical and thermal conductivity flexible base material and a preparation method thereof, first carbonizing and blackleading the polyimide thin film, doping nano-metal to the polyimide thin film, and performing ion implantation and ion exchange; performing plasma irradiation modification treatment on the surface of the material to form an heterogeneous surface layer; then forming a metal conductor layer on the heterogeneous surface layer by physical vapor deposition (PVD) or chemical vapor deposition (CVD), and finally obtaining the flexible base material which is super-flexible, high-ductility, high electrical and thermal conductivity and high-frequency.

In the preferred embodiments, the polyimide thin film with the molecular weight greater than 1,000,000 is obtained by adopting a spraying process, the film has high tensile strength and high film quantity density, and the quantum carbon-based film with high strength, high density and high thermal conductivity is prepared; In the carbonization and blackleading process for preparing a quantum carbon-based film, nano-metal is injected into a quantum carbon-based film carrier through ion implantation and ion exchange, the film quantity is increased, a heterogeneous surface layer is formed on the surface of the quantum carbon-based film through plasma modification process, and an embedded metal conductor layer is formed on the heterogeneous surface layer through PVD (preferably magnetron sputtering technology) or CVD, preferably, A C-C-FPC, C-C-COF or C-C-FCCL flexible circuit base material having ultra-flexibility, high ductility, high electrical conductivity, high thermal conductivity (above 1,500 W/mk), high frequency performance (HF 3-30 MHz) is obtained further by a laser annealing treatment.

The present invention can effectively meet the high requirements of the 5G era on the flexible electronic base material, such as: higher conductivity, high thermal conductivity, higher temperature resistance, high voltage, high density, low thermal expansion coefficient and the like, so as to meet the requirements of high interconnection, high speed and low power consumption in the 5G world. C-C-FPC, C-C-COF and flexible circuit substrate material C-C-FCCL with high conductivity, super flexibility, high thermal conductivity and high frequency are prepared by depositing and embedding conductive metal in a quantum carbon-based film in the method of the present invention, and the defects of the traditional two-layer method FCCL substrate material are overcome.

In a preferred embodiment of the present invention, the metal conductor layer is deposited on the heterogeneous surface layer by PVD (magnetron sputtering) or CVD vacuum evaporation, preferably PVD is adopted and is realized in a magnetron sputtering mode, the process is simple, and the manufactured flexible base material such as C-C-FCCL has improved compactness, high ductility, high conductivity, super flexibility, high thermal conductivity and high frequency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

none

### DETAILED DESCRIPTION

Hereinafter, embodiments of the present invention will be described in detail. It should be emphasized that the following description is exemplary only and is not intended to limit the scope of the invention and application thereof.

In one embodiment, a preparation method of a super-flexible high electrical and thermal conductivity flexible base material, comprising the steps of:

S1. carbonizing and blackleading the polyimide thin film, doping nano-metal to the polyimide thin film, and performing ion implantation and ion exchange; performing carbonizing and blackleading treatment to make the nano monoclinic crystal phase in the film to be changed into a tetragonal crystal, and the single crystal is changed into a superlattice;

S2. performing plasma irradiation modification treatment on the surface of quantum carbon-based film, the material obtained after the step S1, to form a heterogeneous surface layer; and

S3. forming a metal conductor layer on the heterogeneous surface layer by physical vapor deposition (PVD) or chemical vapor deposition (CVD), so as to obtain the super-flexible high-ductility high electrical and thermal conductivity flexible substrate.

In a preferred embodiment, in step S1, transition nano-metal is doped, preferably selected from group VIII cobalt, nickel, ruthenium and lanthanum; preferably, the nanometer is a mixture of 2,000 nm and 400 nm; preferably, the nano-metal forming the upper layer of the surface of the material is cobalt and the nano-metal of the lower layer of the surface is nickel, more preferably, the thickness of the lower layer of the surface is 500 nm. By preferably doping transition nano-metal nickel and cobalt, the heterogeneous surface and the ductility can be effectively improved.

In a preferred embodiment, in step S1, two or more of the three protective gases N, Ar, Ne are mixed and used in the carbonization and blackleading treatment, preferably 50% of N and 50% of Ar are mixed and used in the carbonization, preferably 50% of Ar and 50% of Ne are mixed and used in the blackleading process. This design is very helpful for oxidation resistance.

During carbonization and blackleading process, the mixed protective gas effectively protects the surface from the influences of oxidation and air pressure. High purity neon is also optional in blackleading.

In a preferred embodiment, the nano-metal is doped with the protective gas at a pressure of 50 Kpa. And can be provided in a vacuum system to undergo accelerated treatment.

In a preferred embodiment, before step S1, further comprising the steps of manufacturing the polyimide thin film:

S01. hybridizing anhydride containing phenyl with diamine to obtain a thermoplastic polyimide resin precursor; and

S02. preparing a polyimide thin film by using the thermoplastic polyimide resin precursor;

in step S01, dissolving 30-60 parts by volume of 2,2-bis[4-(4-aminophenoxy) phenyl] propane (BAPP), 30-60 parts by volume of 4,4′-diaminodiphenyl ether (4,4′-ODA) and 7-14 parts by volume of diamino dianthryl ether in N,N-dimethylformamide (DMF), adding 30-60 parts by volume of 3,3′,4,4′-benzophenone tetracarboxylic dianhydride (BTDA), then adding 20-40 parts by volume of pyromellitic dianhydride (PMDA), after a period of reaction, additionally adding 3,3′,4,4′-benzophenone tetracarboxylic dianhydride (BTDA) and/or pyromellitic dianhydride (PMDA) and obtaining a polyimide resin precursor with thermoplasticity, heat resistance and freedom degree; preferably, the total moles of 3,3′,4,4′-benzophenone tetracarboxylic dianhydride (BTDA) and pyromellitic dianhydride (PMDA) is made approximately equal to the total moles of 2,2-bis[4-(4-aminophenoxy) phenyl] propane (BAPP), 4,4′-diaminodiphenyl ether (4,4′-ODA) and diamino dianthryl ether.

In a preferred embodiment, in step S02, a diamino dianthryl ether is used for gel synthesis with the thermoplastic polyimide resin precursor, and a blowout type spraying method is used for uniformly forming a film to obtain a heterogeneous hybridized polyimide thin film; preferably, the gel synthesis is performed above −100° C., preferably the diamino dianthryl ether has a hybridized molecular weight greater than 1,000,000; preferably, the hybridization time is several hours, preferably greater than 5 h, most preferably 6.5 h.

In a preferred embodiment, in step S3, physical vapor deposition (PVD) is performed by a magnetron sputtering technique; preferably, the purity of the conductor target source is 99.999%, and is selected from. Al, Ni, Cu, Si, Au, Ag, microcrystalline silver powder, preferably selected from nickel, copper, silver copper powder and microcrystalline silver powder; preferably, the sputter thickness is 2,000 nm, 1,000 nm or 500 nm, more preferably 500 nm.

Copper and silver copper powders are preferred in PVD magnetron sputtering, so that the compactness, high ductility, high conductivity, super flexibility, high thermal conductivity and high frequency of the manufactured C-C-FCCL flexible base material can be improved.

In a preferred embodiment, in step S3, physical vapor deposition (PVD) or chemical vapor deposition (CVD) is further performed by evaporation.

In a preferred embodiment, the preparation method further comprises the steps of:

S4. annealing the material obtained in the step S3, preferably by a laser annealing technology.

In a preferred embodiment, in step S4, annealing treatment is performed at a temperature not lower than 3,200° C. to make the base film material expand, deoxidize and replace, transform crystal phase change to meet the high-orientation requirement of the superlattice.

In another embodiment, the super-flexible high electrical and thermal conductivity flexible base material is a super-high-conductivity and thermal-conductivity flexible base material obtained by using the preparation method of any of the foregoing embodiments.

The preparation method of specific embodiments is further described below.

Specific methods for manufacturing quantum carbon-based film may also be referred to the methods disclosed in the applicant's prior patent application CN 109776826 A.

In a preferred embodiment, manufacturing the polyimide thin film first comprising the steps of:

S01. hybridizing anhydride containing phenyl with diamine to obtain a thermoplastic polyimide resin precursor; and

S02. preparing a polyimide thin film by using the thermoplastic polyimide resin precursor;

in step S01. hybridizing anhydride containing phenyl with diamine to obtain a thermoplastic polyimide resin precursor.

preferably, step S01 comprising:

dissolving 30-60 parts by volume of 2,2-bis[4-(4-aminophenoxy) phenyl] propane (BAPP), 30-60 parts by volume of 4,4′-diaminodiphenyl ether (4,4′-ODA) and 7-14 parts by volume of diamino dianthryl ether (also known as heterodiamine, the structural formula is

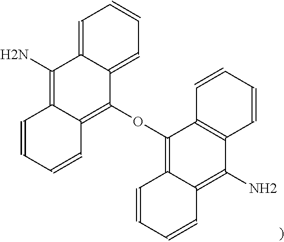 [SMILES: Nc1c2ccccc2c(Oc2c3ccccc3c(N)c3ccccc23)c2ccccc12]

in N,N-dimethylformamide (DMF), adding 30-60 parts by volume of 3,3′,4,4′-benzophenone tetracarboxylic dianhydride (BTDA), then adding 20-40 parts by volume of pyromellitic dianhydride (PMDA), after a period of reaction, additionally adding 3,3′,4,4′-benzophenone tetracarboxylic dianhydride (BTDA) and/or pyromellitic dianhydride (PMDA) and obtaining a polyimide resin precursor with thermoplasticity, heat resistance and freedom degree.

In a more preferred embodiment, in step S01, the total moles of 3,3′,4,4′-benzophenone tetracarboxylic dianhydride (BTDA) and pyromellitic dianhydride (PMDA) is made approximately equal to the total moles of 2,2-bis[4-(4-aminophenoxy) phenyl] propane (BAPP), 4,4′-diaminodiphenyl ether (4,4′-ODA) and diamino dianthryl ether.

In a preferred embodiment, in step S02, a diamino dianthryl ether is used for gel synthesis with the thermoplastic polyimide resin precursor, and a blowout type spraying method is used for uniformly forming a film to obtain a heterogeneous hybridized polyimide thin film.

In a more preferred embodiment, in step S02, the gel synthesis is performed above −100° C. Preferably the diamino dianthryl ether has a hybridized molecular weight greater than 1,000,000.

In step S02, a diamino dianthryl ether is used for gel synthesis with the thermoplastic polyimide resin precursor, and a blowout type spraying method is used for uniformly forming a film. The heterodiamine (diamino dianthryl ether) has a hybridized molecular weight greater than 1,000,000, is subjected to gel synthesis at a temperature of greater than −100° C., and is uniformly formed into a film through a blowout type spraying method. The high-density polyimide thick film is prepared by volatilizing a solvent through a blowout apparatus and isolating the solvent from moisture. The specific method may be referred to the method disclosed in the applicant's prior patent application CN 109776826 A. Polyimide thin films are obtained with molecular weights greater than 1,000,000, which refers to the relative molecular mass being 1/12 of the atomic mass, the molecular mass being numerically equal to the molar mass.

In addition, the method for manufacturing the polyimide thin film may also be in relation to the specific method described in paragraph [0032] of CN 109776826 A. Generally, the polyimide thin film is prepared by increasing the parts by volume of the anisotropic diamine by 30-60 parts while increasing the parts by volume of the anhydride containing a phenyl group by 30-60 parts.

Next, in a preferred embodiment, in step S1, when dehydrogenating and denitrifying the film material during carbonization and blackleading process, and the nano-metal is doped with the protective gas at a pressure of 50 Kpa. carbonizing and blackleading the polyimide thin film, doping nano-metal to the polyimide thin film, and performing ion implantation and ion exchange, wherein, making the nano monoclinic crystal phase in the film change into a tetragonal crystal, and the single crystal is changed into a superlattice.

For doping nano-metal, particularly when dehydrogenating and denitrifying during the blackleading process, the nano-metal is doped with the protective gas at a gas pressure of 50 Kpa. During blackleading, the base film starts an expansion period at 2,800° C., a single crystal and a monoclinic crystal change, phase a carbon element lattice is complete, the nano-metal is injected during deoxidation, the nano-metal element changes phase from a transition element to a tetragonal lattice, and meanwhile, the single crystal is changed into a superlattice.

In a preferred embodiment, in step S3, physical vapor deposition is performed on a heterogeneous surface layer formed by plasma irradiation modification treatment of a quantum carbon-based film by a magnetron sputtering technique so as to realize high-speed low-temperature damage-free sputtering at a low gas pressure. Preferably, the purity of the conductor target source used is 99.999%, selected from Al, Ni, Cu, Si, Au, Ag, microcrystalline silver powder and so on, preferably selected from nickel, copper, silver copper powder and microcrystalline silver powder, and particularly can be selected according to the requirements of C-C-FPC and C-C-COF. If the mixture is selected, pretreatment is preferably performed firstly, uniform dispersion is achieved through mechanical mixing, the purity is improved, the reaction activity of the material is excited, and the sintering humidity of the material is reduced. Sputtering in the present invention can be controlled to form a thicknesses of 2,000 nm, 1,000 nm or 500 nm, preferably 500 nm, with the nanometers being bonded to each other to form a compact super-flexible circuit base material C-C-FCCL.

In a preferred embodiment, in step S4, annealing process is performed at a temperature not lower than 3,200° C. to make the base film material expand, deoxidize and replace, transform crystal phase change to meet the high-orientation requirement of the superlattice. In order to reduce the defect grain boundaries and transition from one axis to two axes, the annealing process is preferably performed at an extremely high temperature of 3,200° C. Through cyclic expansion, deoxidation replacement and transformation of crystal phase change, the layered plane direction is aligned with the vertical direction to achieve the requirement of high orientation, the superlattice is oriented greater than 87%, so that van der waals force is optimized to make the flexible carbon-based film reach a K value of 1,900±100 W/m⁻¹k⁻¹, without wrinkle and super elasticity, and fold greater than 8000 times at 10% elongation limit, and bent greater than 100,000 cycles at 180° C. With a semiconductor carrier concentration up to 1.6×10²⁰, the flexible carbon base film has high thermal conductivity, due, at least in part, to high concentration, core vibration of particles in the crystal lattice, scaling of domain size, formation of interfacial boundary pores, it has high crystallinity and reduced defect grain boundaries, has a thermal conductivity K value reaches 1488 W/m⁻¹k⁻¹ at a thickness of 30 μm with very limited strain, which realized superflexibility in the range of 0.2%-0.4%.

By preferably using an annealing process with an extremely high temperature not less than 3,200° C., the defective grain boundaries are effectively eliminated. The defect means that there is no defect in oxygen-containing functional groups, nanocavities and SP₃ carbon bonds on the surface of the compound semiconductor C-C-X base film. The crystal in the super-elastic carbon-carbon-hybrid alkene sheet can be folded, with the large elongation adapt to the external tension, it can provide sufficient degree of freedom for bending deformation. At the same time, high temperature annealing reduces the phonon scattering center, the defects in the lattice structure and in the functional groups of carbon-carbon-X base films.

In the preferred embodiment, a thermoplastic polyimide resin precursor is obtained by hybridizing anhydride containing phenyl and diamine, a high-density polyimide thin film is prepared from the precursor, preferably, a high-density thick film is prepared with double-inclined heterogeneous hybridized polyimide having high heat resistance and degree of freedom by adopting a chemical spraying method; Carbonization and blackleading high-temperature process are performed on the obtained polyimide thin film, and ion implantation and ion exchange are performed by doping a nano-metal material to change the nano monoclinic crystal phase into a tetragonal crystal; and the high-temperature annealing process is optimized to make the base film material expand, deoxidize and replace, make the metal nano-element liquid crystalline phase change and the defect crystal boundary reduce, so as to ensure that the layered plane direction is aligned with the vertical direction and has higher orientation performance, the superlattice is oriented greater than 87%, thus the van der waals force is optimized. The experimental results show that the compound semiconductor material C-C-X with band gap of 2.3 EV, carrier concentration of 1.6×10²⁰ cm⁻³, resistivity of 2.310E-04 (Ω·m/cm), high temperature, high voltage, high frequency performance, large width of 920-1200 mm, super-flexible, ultra-thin layer microstructure can be obtained.

Therefore, the invention provides a super-flexible high electrical and thermal conductivity flexible base material and a preparation method thereof, first carbonizing and blackleading the polyimide thin film, doping nano-metal to the polyimide thin film, and performing ion implantation and ion exchange; performing plasma irradiation modification treatment on the surface of the material to form an heterogeneous surface layer; then forming a metal conductor layer on the heterogeneous surface layer by physical vapor deposition (PVD) or chemical vapor deposition (CVD), and finally obtaining the flexible base material which is super-flexible, high-ductility, high electrical and thermal conductivity and high-frequency.

In the preferred embodiments, the polyimide thin film with the molecular weight greater than 1,000,000 is obtained by adopting a spraying process, the film has high tensile strength and high film quantity density, and the quantum carbon-based film with high strength, high density and high thermal conductivity is prepared; In the carbonization and blackleading process for preparing a quantum carbon-based film, nano-metal is injected into a quantum carbon-based film carrier through ion implantation and ion exchange, the film quantity is increased, a heterogeneous surface layer is formed on the surface of the quantum carbon-based film through plasma modification process, and an embedded metal conductor layer is formed on the heterogeneous surface layer through PVD (preferably magnetron sputtering technology) or CVD, preferably, A C-C-FPC, C-C-COF or C-C-FCCL flexible circuit base material having ultra-flexibility, high ductility, high electrical conductivity, high thermal conductivity (above 1,500 W/mk), high frequency performance (HF 3-30 MHz) is obtained further by a laser annealing treatment.

The present invention can effectively meet the high requirements of the 5G era on the flexible electronic base material, such as: higher conductivity, high thermal conductivity, higher temperature resistance, high voltage, high density, low thermal expansion coefficient and the like, so as to meet the requirements of high interconnection, high speed and low power consumption in the 5G world. C-C-FPC, C-C-COF and flexible circuit substrate material C-C-FCCL with high conductivity, super flexibility, high thermal conductivity and high frequency are prepared by depositing and embedding conductive metal in a quantum carbon-based film in the method of the present invention, and the defects of the traditional two-layer method FCCL substrate material are overcome.

In a preferred embodiment of the present invention, the metal conductor layer is deposited on the heterogeneous surface layer by PVD (magnetron sputtering) or CVD vacuum evaporation, preferably PVD is adopted and is realized in a magnetron sputtering mode, the process is simple, and the manufactured flexible base material such as C-C-FCCL has improved compactness, high ductility, high conductivity, super flexibility, high thermal conductivity and high frequency.

The foregoing is a further detailed description of the present invention in connection with specific/preferred embodiments, and is not to be construed as limiting the present invention to such specific embodiments. It will be apparent to those skilled in the art that various substitutions and modifications can be made to the described embodiments without departing from the spirit of the present invention, and it is intended that such substitutions and modifications fall within the scope of the present invention. In the description of this specification, reference to the description of the terms “one embodiment”, “some embodiments”, “preferred embodiments”, “examples”, “specific examples”, or “some examples”, etc., means that a particular feature, structure, material, or characteristic described in connection with the embodiment or example is included in at least one embodiment or example of the present invention. In the present specification, schematic expressions of the above terms are not necessarily directed to the same embodiments or examples. Furthermore, the particular features, structures, materials, or characteristics described may be combined in any one or more embodiments or examples in a suitable manner. Moreover, various embodiments or examples described in this specification, as well as features of various embodiments or examples, may be incorporated and combined by those skilled in the art without departing from the scope of the invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A preparation method of a super-flexible high electrical and thermal conductivity flexible base material, comprising the steps of:
S1. carbonizing and blackleading the polyimide thin film, doping nano-metal to the polyimide thin film, and performing ion implantation and ion exchange;
S2. performing plasma irradiation modification treatment on a surface of the material obtained after the step S1 to form a heterogeneous surface layer; and
S3. forming a metal conductor layer on the heterogeneous surface layer by physical vapor deposition (PVD) or chemical vapor deposition (CVD), so as to obtain the super-flexible high-ductility high electrical and thermal conductivity flexible base material.

2. The preparation method of claim 1, wherein in step S1, transition nano-metal is doped, preferably selected from cobalt, nickel, ruthenium and lanthanum in group VIII; preferably, the nanometer is a mixture of 2,000 nm and 400 nm; preferably, the nano-metal forming an upper layer of a surface of the material is cobalt and the nano-metal of an lower layer of the surface is nickel, more preferably, a thickness of the lower layer of the surface is 500 nm.

3. The preparation method of claim 1, wherein in the step S1, two or more of three protective gases N, Ar and Ne are mixed and used in the carbonization and blackleading treatment, preferably 50% of N and 50% of Ar are mixed and used in the carbonization, preferably 50% of Ar and 50% of Ne are mixed and used in the blackleading treatment; preferably, the nano-metal is doped with the protective gas at a pressure of 50 Kpa.

4. The preparation method of claim 1, wherein before the step S1, the preparation method further comprises the steps of manufacturing the polyimide thin film:
S01. hybridizing anhydride containing phenyl with diamine to obtain a thermoplastic polyimide resin precursor; and
S02. preparing a polyimide thin film by using the thermoplastic polyimide resin precursor;
in step S01, dissolving 30-60 parts by volume of 2,2-bis[4-(4-aminophenoxy) phenyl] propane (BAPP), 30-60 parts by volume of 4,4′-diaminodiphenyl ether (4,4′-ODA) and 7-14 parts by volume of diamino dianthryl ether in N,N-dimethylformamide (DMF), adding 30-60 parts by volume of 3,3′,4,4′-benzophenone tetracarboxylic dianhydride (BTDA), then adding 20-40 parts by volume of pyromellitic dianhydride (PMDA), after a period of reaction, additionally adding 3,3′,4,4′-benzophenone tetracarboxylic dianhydride (BTDA) and/or pyromellitic dianhydride (PMDA) and obtaining a polyimide resin precursor with thermoplasticity, heat resistance and freedom degree; preferably, the total moles of 3,3′,4,4′-benzophenone tetracarboxylic dianhydride (BTDA) and pyromellitic dianhydride (PMDA) is made equal to the total moles of 2,2-bis[4-(4-aminophenoxy) phenyl] propane (BAPP), 4,4′-diaminodiphenyl ether (4,4′-ODA) and diamino dianthryl ether.

5. The preparation method of claim 4, wherein in step S02, a diamino dianthryl ether is used for gel synthesis with the thermoplastic polyimide resin precursor, and a blowout type spraying method is used for uniformly forming a film to obtain a heterogeneous hybridized polyimide thin film; preferably, the gel synthesis is performed above −100° C., preferably the diamino dianthryl ether has a hybridized molecular weight greater than 1,000,000; preferably, the hybridization time is 5 h or more, preferably 6.5 h.

6. The preparation method of claim 1, wherein in the step S3, physical vapor deposition (PVD) is performed by a magnetron sputtering technique; preferably, the purity of the conductor target source is 99.999%, and is selected from Al, Ni, Cu, Si, Au, Ag and microcrystalline silver powder, preferably selected from nickel, copper, silver copper powder and microcrystalline silver powder; preferably, the sputter thickness is 2,000 nm, 1,000 nm or 500 nm, more preferably 500 nm.

7. The production method of claim 1, wherein in the step S3, physical vapor deposition (PVD) or chemical vapor deposition (CVD) is performed by vacuum evaporation.

8. The preparation method of claim 1, further comprising the steps of:
S4. annealing the material obtained in the step S3, preferably by a laser annealing technique.

9. The preparation method of claim 8, wherein in the step S4, annealing treatment is performed at a temperature not lower than 3,200° C. to make the base film material expand, deoxidize and replace, transform crystal phase change to meet the high-orientation requirement of the superlattice.

10. A super-flexible high electrical and thermal conductivity flexible base material, being a super-flexible high-conductivity and thermal-conductivity flexible base material obtained by the preparation method of claim 1.
